(19) United States
(12) Patent Application Publication
(10) Pub. No.: US 2026/0266930 A1
(43) Pub. Date: Sep. 10, 2026

(54) SPIN-ACCUMULATION SENSORS

(71) Applicant: Regents of the University of Minnesota, Minneapolis, MN (US)

(72) Inventors: Christopher Leighton, Minneapolis, MN (US); Benjamin Kaiser, Maastricht (NL); Justin Ramberger, Boston, MA (US)

(21) Appl. No.: 19/458,160

(22) Filed: Jan. 23, 2026

Related U.S. Application Data
(60) Provisional application No. 63/750,017, filed on Jan. 27, 2025.

(51) Int. Cl. G01R 33/09; G11B 5/39; H10N 50/10; H10N 50/85

(52) U.S. Cl. CPC G01R 33/093; G11B 5/3912; H10N 50/10; H10N 50/85; G11B 2005/3996

(57) ABSTRACT

A spin-accumulation sensor may include a non-magnetic channel extending in a direction along a sensor axis, and a ferromagnetic layer. The non-magnetic channel may have a thickness in a direction transverse to the sensor axis of 10 nm or less.

### CROSS-REFERENCE TO RELATED APPLICATIONS

This application claims the benefit of U.S. Provisional Patent Application Ser. No. 63/750,017, filed Jan. 27, 2025, which is incorporated by reference herein in its entirety.

### STATEMENT REGARDING FEDERALLY SPONSORED RESEARCH OR DEVELOPMENT

This invention was made with government support under DMR2103711 awarded by the National Science Foundation. The government has certain rights in the invention.

### TECHNICAL FIELD

The present disclosure relates to spin-accumulation sensors.

### BACKGROUND

Magnetic hard disk drives continue to advance, driven in large part by an exponentially rising demand for cloud data storage (approximately 90% of current cloud storage infrastructure is based on magnetic storage). Such drives include a read sensor that is currently a magnetoresistive sensor configured to detect a magnetic field emanating from a bit of data stored on magnetic media, and to generate an electrical read-out signal indicative of the magnetization orientation of the bit. Certain types of read sensors include magnetic tunnel junctions. However, magnetic tunnel junctions exhibit a relatively high electrical resistance-area product, which may interfere with recording applications as pertinent sensing dimensions are scaled down (e.g., to achieve higher storage densities). A lower electrical resistance technology continues to be sought for next-generation read sensor technologies.

### SUMMARY

The present disclosure describes spin-accumulation sensors. Spin-accumulation sensors are an alternative to read sensors based on magnetic tunnel junctions. Spin-accumulation sensors are based on metallic non-local spin valves (NLSVs). Spin-accumulation sensors may be used in read sensors of hard disk drives to detect magnetic fields indicative of stored data. A relatively higher storage density can be achieved if relatively smaller sensor dimensions are used, particularly the non-magnetic metal thickness. However, spin-accumulation sensors typically exhibit a reduction in signal strength as sensor dimensions are reduced. For example, reducing the thickness of the non-magnetic channel in NLSVs from relatively higher thicknesses such as 100 to 300 nm, to lower thicknesses of less than 100 nm leads to a reduction in signal strength. Thus, it was previously believed that a large signal strength and a very low thickness were contrary goals, and that both could not be achieved together.

In some examples according to the present disclosure, an example spin-accumulation sensor includes a non-magnetic channel extending in a direction along a sensor axis, and a ferromagnetic layer. The non-magnetic channel may have a thickness in a direction transverse to the sensor axis of 10 nm or less.

It was surprisingly found that reducing the thickness of the non-magnetic channel to 10 nm or less leads to an increase in signal strength generated by the spin-accumulation sensor. For example, a spin-accumulation sensor having a non-magnetic channel thickness of 4 nm was found to exhibit a signal enhancement of approximately 10 times compared to an identical sensor with a thickness of 13 nm. Including a moderate resistance-area product barrier between the ferromagnets and non-magnetic layers further increased the signal by an additional factor of 500. Spin-accumulation sensors according to the present disclosure may exhibit a relatively higher signal strength while having relatively smaller sensor dimensions compared to spin-accumulation sensors having a non-magnetic channel thickness of greater than 10 nm.

The details of one or more examples of the techniques of this disclosure are set forth in the accompanying drawings and the description below. Other features, objects, and advantages of the techniques will be apparent from the description and drawings, and from the claims.

### BRIEF DESCRIPTION OF THE DRAWINGS

The summary, as well as the following detailed description, is further understood when read in conjunction with the appended drawings. For the purpose of illustrating the disclosure, examples are shown in the drawings; however, the disclosure is not limited to the specific techniques, compositions, and devices disclosed. In addition, the drawings are not necessarily drawn to scale.

FIG. 1 is a conceptual diagram illustrating a perspective view of an example spin-accumulation sensor.

FIGS. 2A to 2H are conceptual diagrams illustrating a technique for forming an example spin-accumulation sensor.

FIG. 3 is a chart illustrating an increase in signal strength with a reduction in a thickness of a non-magnetic channel to under 10 nm.

FIGS. 4A to 4C are two-dimensional greyscale charts of spin signal as a function of resistance-area product, displaying the dependence on tunneling spin polarization, electrode separation, and non-magnetic channel thickness, as determined by an experimentally informed analytical model.

FIG. 5 is a chart illustrating the relationship between non-magnetic channel thickness and spin signal (at various resistance-area products), based on the analytical model of FIGS. 4A to 4C.

### DETAILED DESCRIPTION

The present disclosure may be understood more readily by reference to the following detailed description taken in connection with the accompanying figures and examples, which form a part of this disclosure. It is to be understood that this disclosure is not limited to the specific devices, methods, applications, conditions or parameters described and/or shown herein, and that the terminology used herein is for the purpose of describing particular examples and is not intended to be limiting of the claims. When a range of values is expressed, another example includes from the one particular value and/or to the other particular value. Similarly, when values are expressed as approximations, by use of the antecedent “about,” it will be understood that the particular value forms another example. All ranges are inclusive and combinable. Further, a reference to values stated in a range includes each and every value within that range.

It is to be appreciated that certain features of the disclosure which are, for clarity, described herein in the context of separate examples, may also be provided in combination in a single example. Conversely, various features of the disclosure that are, for brevity, described in the context of a single example, may also be provided separately or in any subcombination.

The present disclosure generally relates to spin-accumulation sensors, and to techniques for forming spin-accumulation sensors. Spin-accumulation sensors may be based on nanoscopic spintronic devices known as metallic non-local spin valves (NLSVs). A spin-accumulation sensor may be configured to inject a charge current from a fixed ferromagnetic layer into a non-magnetic channel, which ultimately leads to spin polarization at a free ferromagnetic layer. This spin polarization at the free ferromagnetic layer may be detected through a non-local voltage (V_{NL}) or resistance (R_{NL}). For example, toggling the magnetizations of the free ferromagnetic layer and the fixed ferromagnetic layer between parallel (P) and antiparallel (AP) states (e.g., by a field emanating from a bit) leads to a change in the non-local resistance (ΔR_{NL}). ΔR_{NL} is a direct measure of the spin polarization at an interface of the non-magnetic channel and the free ferromagnetic layer. The magnitude of ΔR_{NL} is referred to as a “signal strength” of the spin-accumulation sensor. Thus, the signal strength is increased when the magnitude of ΔR_{NL} in response to a sensed magnetic field is increased.

Higher signal strengths promote a reduction in errors and robustness in reading stored data. However, metallic NLSVs have conventionally exhibited a reduction in signal strength with a reduction in sensor dimensions, for example, as a thickness of a non-magnetic metal channel of an NLSV is reduced from 100 to 300 nm to below 100 nm. Thus, a goal of reducing sensor dimensions was hitherto considered to be generally counter to a goal of increasing signal strength.

In example sensors according to the present disclosure, an increased signal strength is achieved by reducing sensor dimensions. It was surprisingly found that reducing a dimension of the non-magnetic channel of a spin-accumulation sensor below a threshold gradually led to an increase in signal strength. In some examples, a spin-accumulation sensor includes a non-magnetic channel (e.g., a non-magnetic metal channel) extending in a direction along a sensor axis; and a ferromagnetic layer (e.g., a spin injector and/or a detector). The non-magnetic channel has a thickness in a direction transverse to the sensor axis of 10 nm or less. Reducing the thickness of the non-magnetic channel to 10 nm or less surprisingly leads to an increase in signal strength of the spin-accumulation sensor, compared to spin-accumulation sensors in which the thickness of the non-magnetic channel is greater than 10 nm.

In addition to increasing the signal strength, reducing the thickness of the non-magnetic channel permits an increase in the density of magnetic storage. For example, a sensor including a non-magnetic channel having a relatively smaller thickness may be used to read a bit stored in a relatively smaller portion of a magnetic storage substrate, compared to another sensor including a non-magnetic channel having a relatively greater thickness. In turn, the increase in density of magnetic storage permits a reduction in overall dimensions of storage media. Further, an increase in density may permit relatively faster reading of data because a read sensor may need to traverse relatively smaller distances to read a given length of stored data.

Spin-accumulation sensors may exhibit spin back-diffusion, which may interfere with signal strength. In particular, spin is injected from a ferromagnetic layer to a non-magnetic channel, which ultimately generates a spin signal. However, the ferromagnetic layer typically has a lower spin resistance compared to that of the non-magnetic channel. Thus, the initially injected spin sinks back from the non-magnetic channel to the ferromagnetic layer (referred to as spin back-diffusion). Such spin back-diffusion reduces sensor signal strength.

To mitigate such spin back-diffusion, in some examples, a spin-accumulation sensor further includes a spin back-diffusion barrier between a non-magnetic channel and a ferromagnetic layer. The spin back-diffusion barrier resists spin back-diffusion, and ultimately results in an increase in signal strength. The spin back-diffusion barrier affects the interfacial resistance-area product (RA product). The RA product is the mathematical product of interfacial area multiplied by interfacial resistance. Typically, as the area A is reduced (e.g., in response to reduction in sensor dimensions), the resistance R increases, leading to a higher RA with a reduction in sensor dimensions. The spin back-diffusion barrier can be configured to generate an RA product that sufficiently reduces spin back-diffusion and increases signal strength.

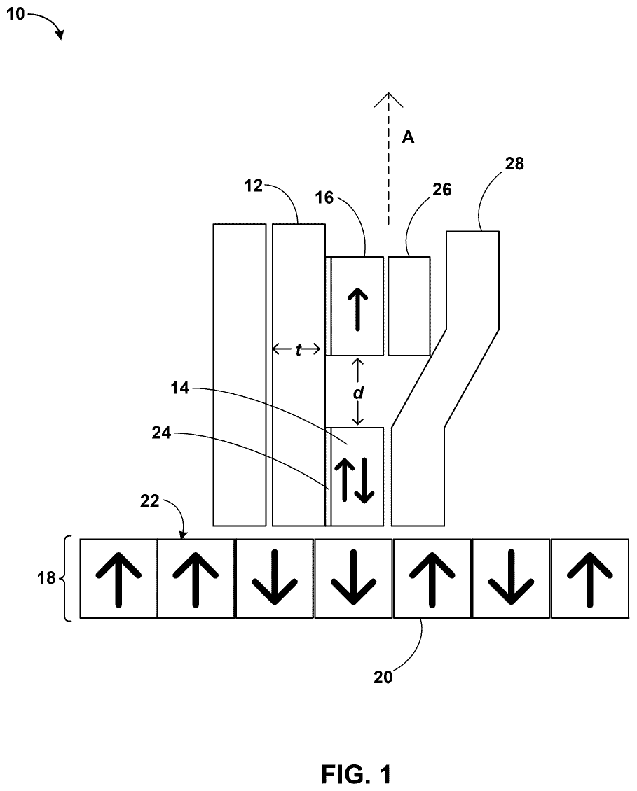

FIG. 1 is a conceptual diagram illustrating a perspective view of an example spin-accumulation sensor 10. Spin-accumulation sensor 10 includes a non-magnetic channel 12 extending in a direction along a sensor axis A, and a ferromagnetic layer 14. Non-magnetic channel 12 may include any suitable non-magnetic metal or alloy. In some examples, non-magnetic channel 12 includes at least one of Al or Mg. Ferromagnetic layer 14 may include any suitable magnetic material. In some examples, ferromagnetic layer 14 includes an alloy including Fe and Co. In some examples, ferromagnetic layer 14 includes CoₐFe_{b}, where a and b are any suitable integers or fractions. In some examples, ferromagnetic layer 14 includes Co₇₈Fe₂₂.

In some examples, ferromagnetic layer 14 is a free ferromagnetic layer, and spin-accumulation sensor 10 further includes a fixed ferromagnetic layer 16 spaced from ferromagnetic layer 14 by a spacing d (in a direction along sensor axis A). Typically, as the spacing d is reduced, a signal-to-noise ratio of spin-accumulation sensor 10 is increased. Both free ferromagnetic layer 14 and fixed ferromagnetic layer 16 are adjacent non-magnetic channel 12.

Spin-accumulation sensor 10 is configured to inject a charge current from fixed ferromagnetic layer 16 into non-magnetic channel 12. For example, a current source may be electrically coupled to fixed ferromagnetic layer 16, which in turn is electrically coupled to non-magnetic channel 12 to inject the charge current. Injecting the charge current generates a non-equilibrium spin polarization in non-magnetic channel 12. This results in a pure diffusive spin current in non-magnetic channel 12. Thus, the passive diffusive spin current in non-magnetic channel 12 leads to spin polarization at free ferromagnetic layer 14. This spin polarization at free ferromagnetic layer 14 may be detected through a non-local voltage (V_{NL}) or resistance (R_{NL}). For example, toggling the magnetizations of free ferromagnetic layer 14 and fixed ferromagnetic layer 16 between parallel (P) and antiparallel (AP) states (e.g., by a field emanating from a bit) leads to a change in the non-local resistance (ΔR_{NL}). ΔR_{NL}, also referred to as a “spin signal” or “sensor signal” of spin-accumulation sensor 10, is a direct measure of the spin polarization at an interface of non-magnetic channel 12 and free ferromagnetic layer 14. The magnitude of ΔR_{NL} is referred to as a “signal strength” of spin-accumulation sensor 10. Thus, the signal strength is increased when the magnitude of ΔR_{NL} in response to a sensed magnetic field is increased.

In some examples, a magnetic storage reader may include spin-accumulation sensor 10. For example, a magnetic storage medium 18 may include bits of data 20 (represented by local orientations of magnetic field of portions of magnetic storage medium 18). Free ferromagnetic layer 14 is spaced from a media surface 22 of magnetic storage medium 18 by an air gap between free ferromagnetic layer 14 and media surface 22. Free magnetic layer 14 is coupled to fixed (pinned) ferromagnetic layer 16 removed from media surface 22, through a non-local spin current in vertical non-magnetic channel 12. As the free magnetization of free ferromagnetic layer 14 responds to the stray field from disk bits 20, ΔV_{NL} and ΔR_{NL} are modulated. Thus, the spin signal of spin-accumulation sensor 10 is indicative of the values of bits 20, and magnetic storage medium 18 may be read by traversing spin-accumulation sensor 10 along a portion of magnetic storage medium 18 including bits 20.

Non-magnetic channel 12 may have a thickness t in a direction transverse to sensor axis A. Because non-magnetic channel 12 mediates spin polarization at fixed ferromagnetic layer 16 (and thus the signal strength of spin-accumulation sensor 10), thickness t of non-magnetic channel 12 influences the signal strength of spin-accumulation sensor 10. As described elsewhere in the present disclosure, it was surprisingly found that reducing thickness t of non-magnetic channel 12 to 10 nm or less increases the signal strength of spin-accumulation sensor 10. At the same time, reducing thickness t of non-magnetic channel 12 allows an increase in lateral thickness (transverse to sensor axis A) of other components of spin-accumulation sensor 10 without increasing an overall lateral dimension of spin-accumulation sensor 10, which may promote a higher signal-to-noise ratio exhibited by spin-accumulation sensor 10. Alternatively, reducing thickness t of non-magnetic channel 12 allows a reduction in the overall lateral dimension of spin-accumulation sensor 10, compared to spin-accumulation sensors having non-magnetic channels of greater thicknesses. Thus, spin-accumulation sensor 10 may exhibit a relatively higher signal strength, while having a lower overall lateral dimension and/or an enhanced signal-to-noise ratio, compared to spin-accumulation sensors having non-magnetic channels of thicknesses greater than 10 nm.

In some examples, thickness t of non-magnetic channel 12 is 10 nm or less (in a direction transverse to sensor axis A). In some examples, thickness t of non-magnetic channel 12 in the direction transverse to sensor axis A is 6 nm or less. In some examples, thickness t of non-magnetic channel 12 in the direction transverse to the sensor axis A is about 4 nm.

Free ferromagnetic layer 14 and/or fixed ferromagnetic layer 16 may have any suitable thickness, and may have a same or different thickness. In some examples, free ferromagnetic layer 14 and/or fixed ferromagnetic layer 16 have a same thickness. In some examples, free ferromagnetic layer 14 has a thickness in the direction transverse to the sensor axis of at least 2 nm. Because thickness t of non-magnetic channel 12 is relatively reduced, the thickness of free ferromagnetic layer 14 and/or fixed ferromagnetic layer 16 may be relatively greater, compared to spin-accumulation sensors having thicknesses of non-magnetic channel greater than 10 nm. For example, a sum of thickness t of non-magnetic channel 12 and the thickness of free ferromagnetic layer 14 may be at least 8 nm. In some examples, the sum of the thickness of non-magnetic channel 12 and the thickness of free ferromagnetic layer 14 is at least 12 nm. In some examples, the sum of the thickness of non-magnetic channel 12 and the thickness of free ferromagnetic layer 14 is at least 20 nm.

Spin-accumulation sensor 10 may further include a spin back-diffusion barrier 24 between non-magnetic channel 12 and free ferromagnetic layer 14. Spin back-diffusion barrier 24 is configured to reduce back-diffusion of spin from non-magnetic channel 12 to free ferromagnetic layer 14. A spin back-diffusion barrier may also be provided between non-magnetic channel 12 and fixed ferromagnetic layer 16. Spin back-diffusion barrier 24 may have any suitable thickness sufficient to mitigate back-diffusion.

Spin back-diffusion barrier 24 may be formed on or applied to a portion of non-magnetic channel 12. Spin back-diffusion barrier 24 may have any suitable composition, for example, configured to resist back-diffusion, while being formable or compatible on or with non-magnetic channel 12. In some examples, spin back-diffusion barrier 24 includes MgOₓ or AlOₓ. For example, non-magnetic channel 12 may include Al, and spin back-diffusion barrier 24 may include AlOₓ. In such examples, spin back-diffusion barrier 24 may be formed by oxidation of a portion of non-magnetic channel 12 (e.g., oxidation of Al to AlOₓ). Thus, the extent of oxidation may be controlled to control a thickness and composition of spin back-diffusion barrier 24.

Likewise, in other examples, non-magnetic channel 12 may include Mg, and spin back-diffusion barrier 24 may include MgOₓ and formed by oxidation of non-magnetic channel 12. While oxidation is described, any other technique may be used to form spin back-diffusion barrier 24 (e.g., vapor deposition or any other suitable techniques). Further, spin back-diffusion barrier 24 may include a same primary metal species or a different metal species (e.g., Al or Mg) compared to non-magnetic channel 12. In some examples, non-magnetic channel 12 includes Al, spin back-diffusion barrier 16 includes AlOₓ, and ferromagnetic layer 14 includes Co₇₈Fe₂₂.

Because the thickness and chemical composition of spin back-diffusion barrier 24 influences RA, the RA is tunable by controlling oxidation of non-magnetic channel to form spin back-diffusion barrier 24 (e.g., Al to AlOₓ) (or otherwise controlling the thickness or composition of spin back-diffusion barrier 24). In some examples, the RA may be tunable over ~8 orders of magnitude (10⁻³ Ωμm²<RA<10⁵ Ωμm²). For example, increase in RA promotes a crossover from diffusive to tunneling charge transport, which substantially boosts the spin signal of spin-accumulation sensor. In some examples, from a transparent limit to RA≈500 Ωμm², ΔR_{NL} may increase by a factor of 500, reaching ΔR_{NL}≈0.15 Ω. In some examples, the RA exhibited by non-magnetic channel 12 is greater than 1×10⁻³ Ωμm². In some examples, the RA exhibited by non-magnetic channel 12 is greater than 1×10⁻² Ωμm², or greater than 1×10⁻¹ Ωμm², or greater than 1×10 Ωμm², or greater than 1×10² Ωμm². In some examples, the RA is at least 500 Ωμm². In some examples, the RA is less than 1 kΩμm².

In some examples, the spin signal (a change in a non-local spin resistance of spin-accumulation sensor 10 in response to a toggling of a magnetization of free ferromagnetic layer 14 and fixed ferromagnetic layer 16) is at least 1 mΩ. In some examples, the spin signal is at least 10 mΩ, at least 100 mΩ, at least 200 mΩ, at least 300 mΩ, at least 400 mΩ, at least 500 mΩ, or at least 600 mΩ. In some examples, an increase in the RA causes the spin signal to increase in magnitude. For example, an RA of 500 Ωμm² may be associated with a spin signal of 150 mΩ.

Spin-accumulation sensor 10 may further include an anti-ferromagnetic layer 26 spaced from non-magnetic channel 12 in a direction transverse to sensor axis A. For example, fixed ferromagnetic layer 16 may be positioned between anti-ferromagnetic layer 26 and non-magnetic channel 12. Anti-ferromagnetic layer 26 may be configured to be a pinning layer configured to pin the magnetic orientation of fixed ferromagnetic layer 16.

Spin-accumulation sensor 10 may further include a pair of shield layers 28. For example, non-magnetic channel 12, anti-ferromagnetic layer 18, free ferromagnetic layer 14, and fixed ferromagnetic layer 20 may be positioned between pair of shield layers 28. Shield layers 28 may be configured to shield one or more components of spin-accumulation sensor 10 from stray fields, example, stray fields from bits other than target bits being red, or fields other than those from magnetic storage medium 18.

A magnetic storage reader may include spin-accumulation sensor 10. For example, a reader head may include or consist of spin-accumulation sensor 10. For example, the reader head may be configured to read values of bits 20 of magnetic storage medium 18.

In some examples, a technique includes forming spin-accumulation sensor 10.

### EXAMPLES

### Example 1

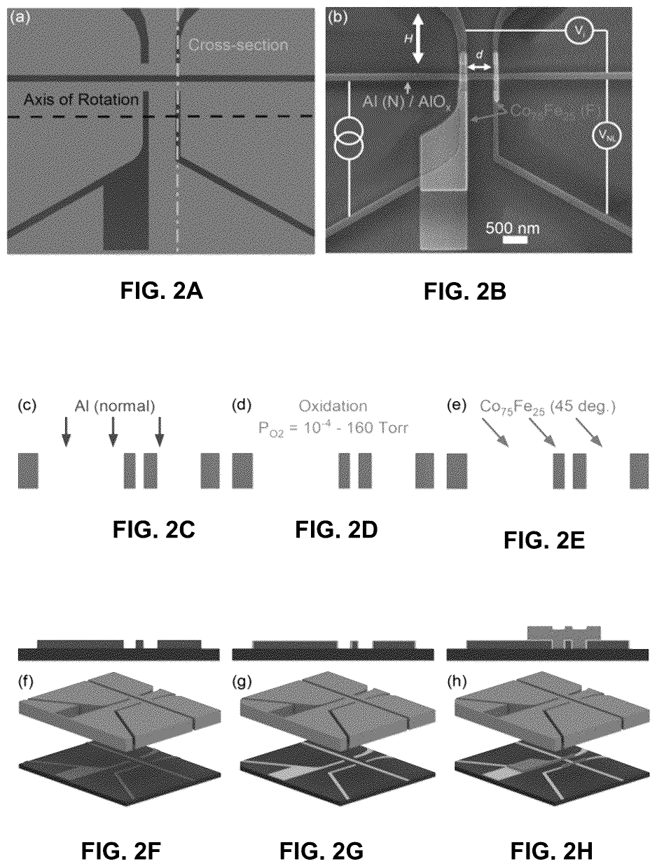

Sample Si/Si—N/Al(t nm)/AlOₓ/Co₇₈Fe₂₂-based NLSVs were fabricated using varied Al oxidation conditions to tune interfacial RA. The thickness t was varied between >100 nm and 4 nm. Electron-beam lithography was first used to generate shadow masks from a PMMA/PMGI (PMMA=poly(methyl methacrylate), PMGI=poly (dimethylglutarimide)) bilayer resist (400 and 600 nm thickness, respectively) on Si/Si—N(300 nm) substrates (FIG. 2A). A multi-angle deposition scheme as shown in FIGS. 2C to 2E was then used to fabricate NLSVs by electron-beam evaporation in an ultra-high vacuum (UHV) chamber with a base pressure of ~1×10⁻¹¹ Torr. Al (from a 99.999% pure target) was first deposited at 5 Å s⁻¹ (the high rate helping to minimize the Al surface roughness) at normal incidence to the substrate, as shown in FIGS. 2C and 2F. Transfer to the load lock of the UHV chamber was then performed, for room-temperature oxidation of the Al in O₂ (99.997%) at varied pressures (P_{O2}=1×10⁻⁴−1.6×10² Torr) for 20 min (FIGS. 2D and 2G). The load lock was then pumped to UHV in ~2 min, and the devices returned to the growth chamber. Using an in-situ rotator, Co₇₈Fe₂₂ (from a 99.95% purity Co₈₀Fe₂₀ target) was then deposited at 45° to the substrate, in the plane of ferromagnetic electrodes (FIGS. 2A, 2E, and 2H). Resist masks were then removed in NMP (N-methyl-2-pyrrolidone), yielding devices such as the one in the scanning electron microscopy (SEM) image in FIG. 2B. This process enables fabrication of Al/AlOx/Co—Fe-based NLSVs with varied interfacial RA, with no break in vacuum. The nominal widths of the Al channel, left Co-Fe electrode, and right Co—Fe electrode, were 130, 180, and 110 nm, respectively, and at each oxidation condition, 60 devices were fabricated on each wafer, at multiple d (with high redundancy), for reliable determination of spin transport parameters.

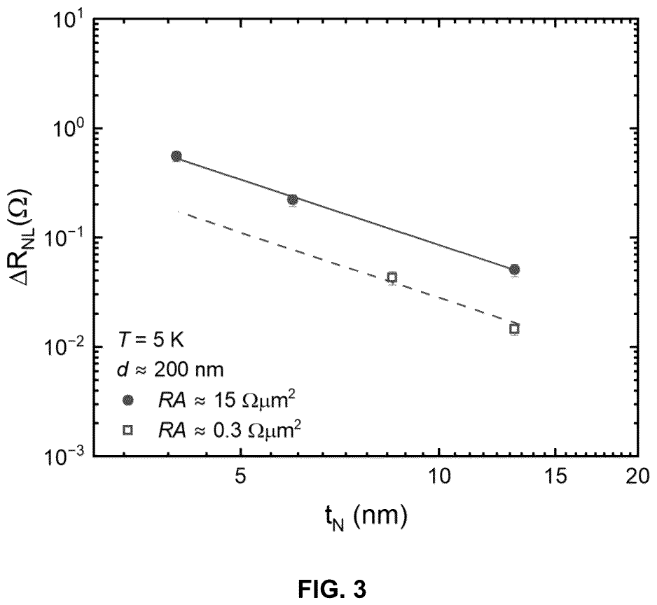

FIG. 3 is a chart illustrating the increase in signal strength with the reduction in the thickness (t) of the non-magnetic channel to under 10 nm. At t=4 nm, the ΔR_{NL} was 600 mΩ for RA≈15 Ωμm², and 200 mΩ for RA≈0.3 Ωμm². The temperature here is 5 K, but the temperature dependence up to room temperature is weak.

### Example 2

Additional non-local spin valve (NLSV) device spin signals were determined in an ultralow-thickness regime. The same fabrication methods, device architecture, and materials selections as in EXAMPLE 1 were used (specifically Al/AlOx/Co—Fe lateral NLSVs fabricated by electron beam lithography). Devices with Al (nonmagnetic metal) thickness of 13.5 nm and below were made. A full temperature and electrode separation dependence was measured at Al thicknesses of 13.5, 8, 6, and 4 nm. The spin signal was found to increase monotonically with decreasing thickness. A 4 nm thickness, the spin signal was almost 10,000 times higher than standard all-metal NLSV devices. These results were achieved at approximate resistance-area (RA) products of 0.3 and 15 Ωμm². Even at such low RA, spin signals above 0.1 Ω were achieved.

### Example 3

An experimentally-informed one-dimensional analytical spin transport model was developed for non-local spin valves, accounting for measured values for parameters including the non-magnetic channel (Al) resistivity, Al spin diffusion length, and both the diffusive and tunneling spin polarizations across Co—Fe/Al interfaces. These parameters depend on temperature, thickness, and the resistance area product defined by the AlOx. Dense data sets for these parameters were used to fit these parameters to attain continuous mathematical descriptions, using physics-based models wherever possible.

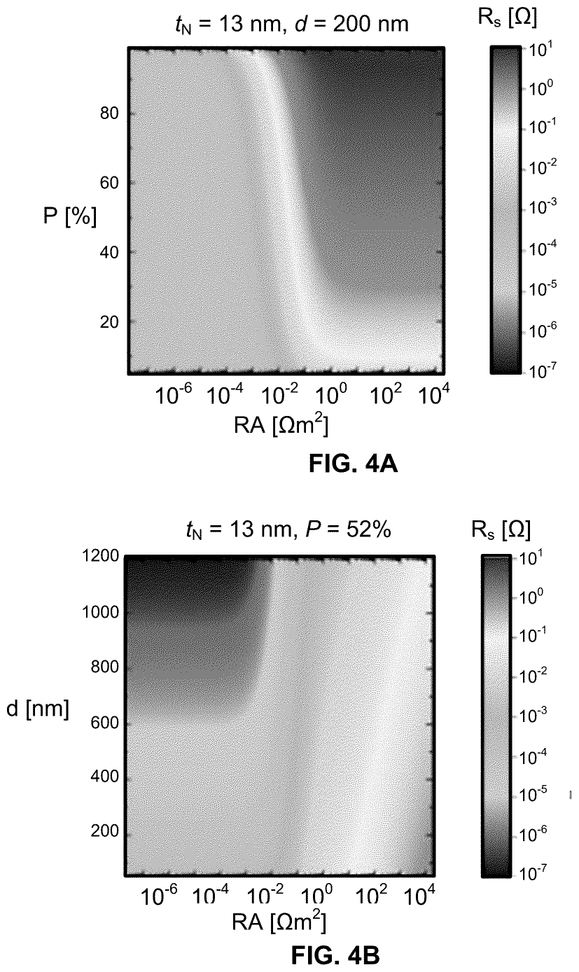

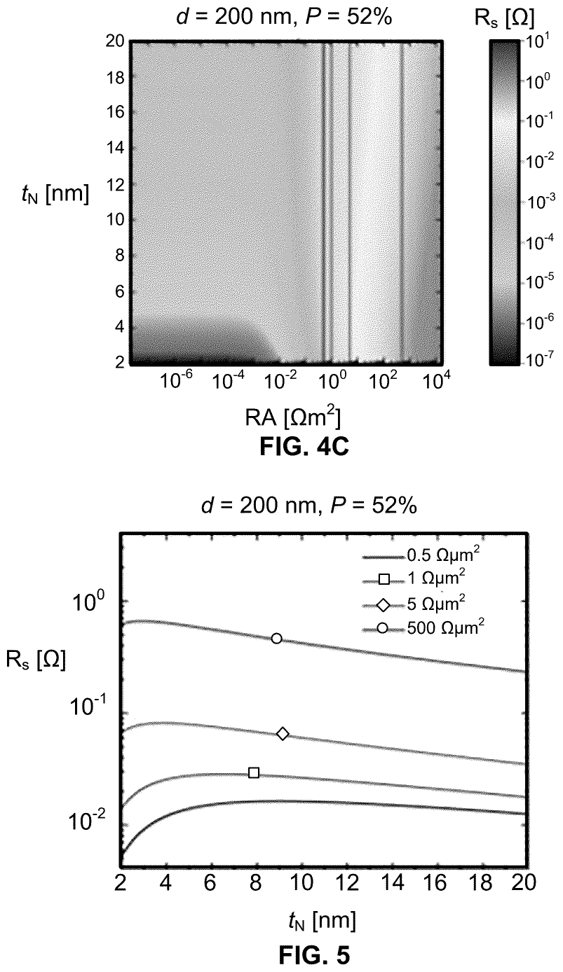

The NLSV spin signal was predicted using the model at various temperatures, thicknesses, resistance area (RA) values, and electrode separations. FIGS. 4A to 4C and FIG. 5 illustrate the results. FIGS. 4A to 4C are two-dimensional grayscale plots of the spin signal as a function of RA on the horizontal axis, and tunneling spin polarization (P), electrode separation (d), and Al thickness (t_{N}) on the vertical axes, respectively. In particular, FIG. 4A graphically illustrates the massive increase in signal with RA due to the diffusive-to tunneling crossover, along with the substantial impact of improving P. FIG. 4B illustrates the expected near-exponential scaling with d. FIG. 4C shows the important thickness dependence, where it can be seen that in the low-RA regime (left side), the spin signal is rapidly suppressed with decreasing thickness (the typical expectation) but that at moderate and high RA (right side) the situation is very different.

FIG. 5 is a chart showing thickness dependence with RA determined based on the analytical model. At high RA, the spin signal was observed to continuously increase on decreasing the thickness, and moderate RA was associated with an appropriate thickness of the non-magnetic channel.

The enhancement in signal found for sample NSLVs were larger than that predicted by the model for corresponding NSLVs.

The following enumerated clauses describe aspects in accordance with the present disclosure.

Clause 1: A spin-accumulation sensor including: a non-magnetic channel extending in a direction along a sensor axis; and a ferromagnetic layer, where the non-magnetic channel has a thickness in a direction transverse to the sensor axis of 10 nm or less.

Clause 2: The spin-accumulation sensor of clause 1, where the thickness of the non-magnetic channel in the direction transverse to the sensor axis is 6 nm or less.

Clause 3: The spin-accumulation sensor of clause 2, where the thickness of the non-magnetic channel in the direction transverse to the sensor axis is about 4 nm.

Clause 4: The spin-accumulation sensor of any of clauses 1 to 3, where the ferromagnetic layer has a thickness in the direction transverse to the sensor axis of at least 2 nm.

Clause 5: The spin-accumulation sensor of clause 4, where a sum of the thickness of the non-magnetic channel and the thickness of the ferromagnetic layer is at least 8 nm.

Clause 6: The spin-accumulation sensor of clause 5, where a sum of the thickness of the non-magnetic channel and the thickness of the ferromagnetic layer is at least 12 nm.

Clause 7: The spin-accumulation sensor of clause 6, where a sum of the thickness of the non-magnetic channel and the thickness of the ferromagnetic layer is at least 20 nm.

Clause 8: The spin-accumulation sensor of any of clauses 1 to 7, further including a spin back-diffusion barrier between the non-magnetic channel and the ferromagnetic layer, where the spin back-diffusion barrier is configured to reduce back-diffusion of spin from the non-magnetic channel to the ferromagnetic layer.

Clause 9: The spin-accumulation sensor of clause 8, where the spin back-diffusion barrier includes MgOₓ or AlOₓ.

Clause 10: The spin-accumulation sensor of clause 9, where the non-magnetic channel includes Al, where the spin back-diffusion barrier includes AlOₓ, and where the ferromagnetic layer includes Co₇₈Fe₂₂.

Clause 11: The spin-accumulation sensor of any of clauses 1 to 10, where a resistance-area product exhibited by the non-magnetic channel is greater than 1×10⁻³ Ωμm².

Clause 12: The spin-accumulation sensor of clause 11, where the resistance-area product exhibited by the non-magnetic channel is greater than 1×10⁻² Ωμm².

Clause 13: The spin-accumulation sensor of any one of clauses 1 to 12, where a change in a non-local spin resistance of the spin-accumulation sensor in response to a toggling of a magnetization of the ferromagnetic layer is at least 100 mΩ.

Clause 14: The spin-accumulation sensor of clause 13, where the change in the non-local spin resistance of the spin-accumulation sensor in response to the toggling of the magnetization of the ferromagnetic layer is at least 600 mΩ.

Clause 15: The spin-accumulation sensor of any of clauses 1 to 14, where the ferromagnetic layer is a free ferromagnetic layer, the spin-accumulation sensor further including: an anti-ferromagnetic layer spaced from the non-magnetic channel in a direction transverse to the sensor axis; and a fixed ferromagnetic layer between the anti-ferromagnetic layer and the non-magnetic channel.

Clause 16: The spin-accumulation sensor of clause 15, further including a pair of shield layers, where the non-magnetic channel, the anti-ferromagnetic layer, the free ferromagnetic layer, and the fixed ferromagnetic layer are between the pair of shield layers.

Clause 17: A magnetic storage reader including the spin-accumulation sensor of any of clauses 1 to 16.

Clause 18: A method including forming the spin-accumulation sensor of any of clauses 1 to 17.

Various examples have been described. Those skilled in the art will appreciate that numerous changes and modifications can be made to the examples described in this disclosure and that such changes and modifications can be made without departing from the spirit of the disclosure. These and other examples are within the scope of the following claims.

What is claimed is:

1. A spin-accumulation sensor comprising:
a non-magnetic channel extending in a direction along a sensor axis; and
a ferromagnetic layer,
wherein the non-magnetic channel has a thickness in a direction transverse to the sensor axis of 10 nm or less.

2. The spin-accumulation sensor of claim 1, wherein the thickness of the non-magnetic channel in the direction transverse to the sensor axis is 6 nm or less.

3. The spin-accumulation sensor of claim 2, wherein the thickness of the non-magnetic channel in the direction transverse to the sensor axis is about 4 nm.

4. The spin-accumulation sensor of claim 1, wherein the ferromagnetic layer has a thickness in the direction transverse to the sensor axis of at least 2 nm.

5. The spin-accumulation sensor of claim 4, wherein a sum of the thickness of the non-magnetic channel and the thickness of the ferromagnetic layer is at least 8 nm.

6. The spin-accumulation sensor of claim 5, wherein a sum of the thickness of the non-magnetic channel and the thickness of the ferromagnetic layer is at least 12 nm.

7. The spin-accumulation sensor of claim 6, wherein a sum of the thickness of the non-magnetic channel and the thickness of the ferromagnetic layer is at least 20 nm.

8. The spin-accumulation sensor of claim 1, further comprising a spin back-diffusion barrier between the non-magnetic channel and the ferromagnetic layer, wherein the spin back-diffusion barrier is configured to reduce back-diffusion of spin from the non-magnetic channel to the ferromagnetic layer.

9. The spin-accumulation sensor of claim 8, wherein the spin back-diffusion barrier comprises MgOₓ or AlOₓ.

10. The spin-accumulation sensor of claim 9, wherein the non-magnetic channel comprises Al, wherein the spin back-diffusion barrier comprises AlOₓ, and wherein the ferromagnetic layer comprises Co₇₈Fe₂₂.

11. The spin-accumulation sensor of claim 1, wherein a resistance-area product exhibited by the non-magnetic channel is greater than 1×10⁻³ Ωμm².

12. The spin-accumulation sensor of claim 11, wherein the resistance-area product exhibited by the non-magnetic channel is greater than 1×10⁻² Ωμm².

13. The spin-accumulation sensor of claim 1, wherein a change in a non-local spin resistance of the spin-accumulation sensor in response to a toggling of a magnetization of the ferromagnetic layer is at least 100 mΩ.

14. The spin-accumulation sensor of claim 13, wherein the change in the non-local spin resistance of the spin-accumulation sensor in response to the toggling of the magnetization of the ferromagnetic layer is at least 600 mΩ.

15. The spin-accumulation sensor of claim 1, wherein the ferromagnetic layer is a free ferromagnetic layer, the spin-accumulation sensor further comprising:
an anti-ferromagnetic layer spaced from the non-magnetic channel in a direction transverse to the sensor axis; and
a fixed ferromagnetic layer between the anti-ferromagnetic layer and the non-magnetic channel.

16. The spin-accumulation sensor of claim 15, further comprising a pair of shield layers, wherein the non-magnetic channel, the anti-ferromagnetic layer, the free ferromagnetic layer, and the fixed ferromagnetic layer are between the pair of shield layers.

17. A magnetic storage reader comprising a spin-accumulation sensor, the spin-accumulation sensor comprising:
a non-magnetic channel extending in a direction along a sensor axis; and
a ferromagnetic layer,
wherein the non-magnetic channel has a thickness in a direction transverse to the sensor axis of 10 nm or less.

18. The magnetic storage reader of claim 17, wherein the non-magnetic channel comprises Al.

19. A method comprising forming a spin-accumulation sensor, the spin-accumulation sensor comprising:
a non-magnetic channel extending in a direction along a sensor axis; and
a ferromagnetic layer,
wherein the non-magnetic channel has a thickness in a direction transverse to the sensor axis of 10 nm or less.

20. The method of claim 19, wherein the non-magnetic channel comprises Al.
